(19) United States
(12) Patent Application Publication
(10) Pub. No.: US 2016/0044832 A1
(43) Pub. Date: Feb. 11, 2016

(54) STORAGE APPARATUS TO PROTECT ELECTRONIC DEVICES FROM DUST AND OVERHEATING

(71) Applicant: ALAN PAUL LEWIS, Gallup, NM (US)

(72) Inventor: ALAN PAUL LEWIS, Gallup, NM (US)

(21) Appl. No.: 14/454,484

(22) Filed: Aug. 7, 2014

(51) Int. Cl. H05K 7/20

(52) U.S. Cl. CPC H05K 7/20554

(57) ABSTRACT

An electronic device storage apparatus for preventing harmful particulate exposure to the device while minimizing a likelihood the device will overheat is provided. The apparatus includes a housing member to store the device, a door mounted to an opening of the housing member and at least one aperture on a back wall oriented parallel to the opening. The at least one aperture is able to secure a wire that connects the device to a power source external to the housing member. A filter is coupled to an aperture in a side wall of the housing member. A fan system is connected to the back wall of the housing member, which pumps heat generated by the device out of the housing member and draws ambient air through the filter and into the housing member, thereby preventing the device from overheating.

### BACKGROUND

The embodiments herein relate generally to electronic devices such as video game consoles.

Electronic entertainment devices such as video game consoles have become increasingly popular and appeal to a wide audience. These devices may allow a user to play video games or DVDs, connect to the Internet to allow the user to interact with other users or stream online videos. Several video game consoles exist on the market such as Sony's PlayStation, Microsoft's Xbox and Nintendo's Wii. One common issue with these devices is the possibility the devices will overheat. These devices comprise fans to cool the electronic components. However, these devices still generate a significant amount of heat during their operation, which can damage the electrical components of the devices. Another common problem is the exposure and collection of harmful particulates such as dust on the devices. These particulates over time can damage electrical components and shorten the lifetime of the devices.

Current devices for protecting electronic devices from dust include compressed air dusters and fabric barriers such as hair nets. However, compressed air dusters are disadvantageous because the user has to continually use them to remove dust from the devices. This is a burden on the user and requires him/her to purchase multiple air dusters throughout the lifetime of the device. The fabric barriers are placed over the electronic devices when they are being stored. However, these devices have a limited use because they have to be removed when the device is operated.

As such, there is a need in the industry for a storage apparatus that effectively protects an electronic device from dust and overheating when in use and while being stored.

### SUMMARY

An electronic device storage apparatus for preventing harmful particulate exposure to the device while minimizing a likelihood the device will overheat when in use is provided. This enhances the lifetime of the device. The apparatus comprises a housing member configured to store the device and comprises a door mounted to an opening of the housing member and at least one aperture on a back wall oriented parallel to the opening, wherein the at least one aperture is configured to secure a wire that connects the device to a power source external to the housing member, a filter detachably coupled to an aperture in a side wall of the housing member, and a fan system operably connected to the back wall of the housing member and configured to pump heat generated by the device out of the housing member and draw ambient air through the filter and into the housing member, thereby preventing the device from overheating.

### BRIEF DESCRIPTION OF THE FIGURES

The detailed description of some embodiments of the invention will be made below with reference to the accompanying figures, wherein the figures disclose one or more embodiments of the present invention.

FIG. 1 depicts a front perspective view of certain embodiments of the electronic device storage apparatus;

FIG. 2 depicts a rear perspective view of certain embodiments of the electronic device storage apparatus;

FIG. 3 depicts an exploded view of certain embodiments of the electronic device storage apparatus;

FIG. 4 depicts a section view of certain embodiments of the electronic device storage apparatus taken along line 4-4 in FIG. 1;

FIG. 5 depicts a section view of certain embodiments of the electronic device storage apparatus illustrating the movement of door 14 and shelf 20; and

FIG. 6 depicts a section view of certain embodiments of the electronic device storage apparatus taken along line 6-6 in FIG. 4.

### DETAILED DESCRIPTION OF CERTAIN EMBODIMENTS

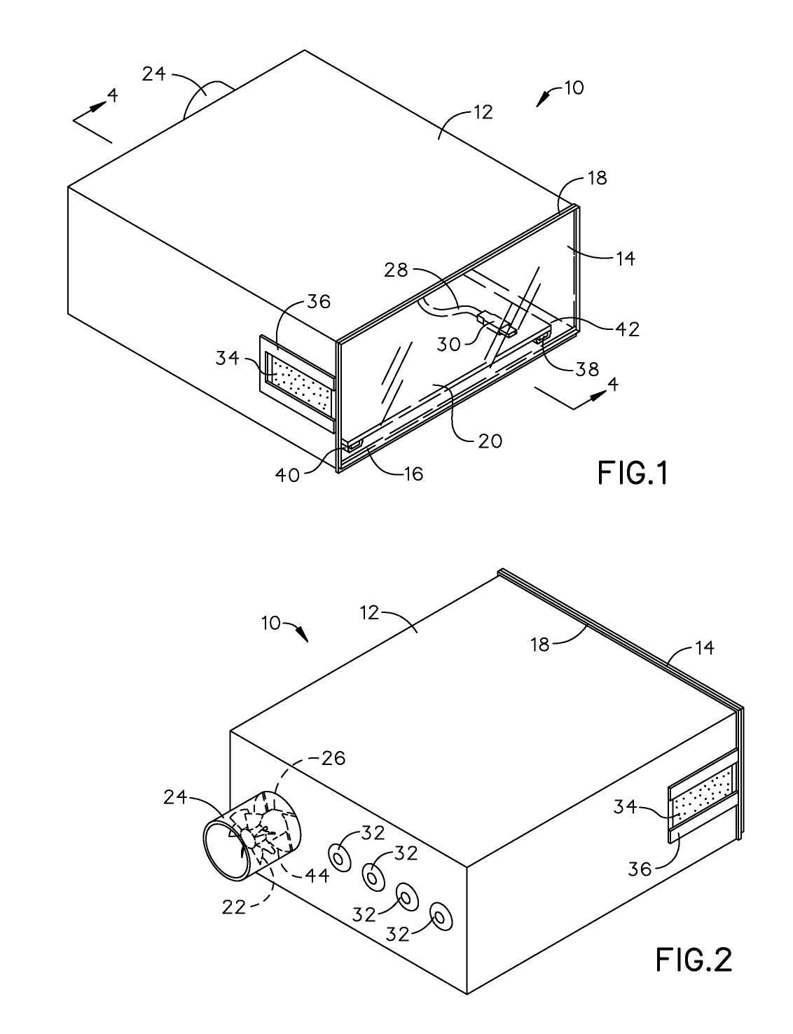

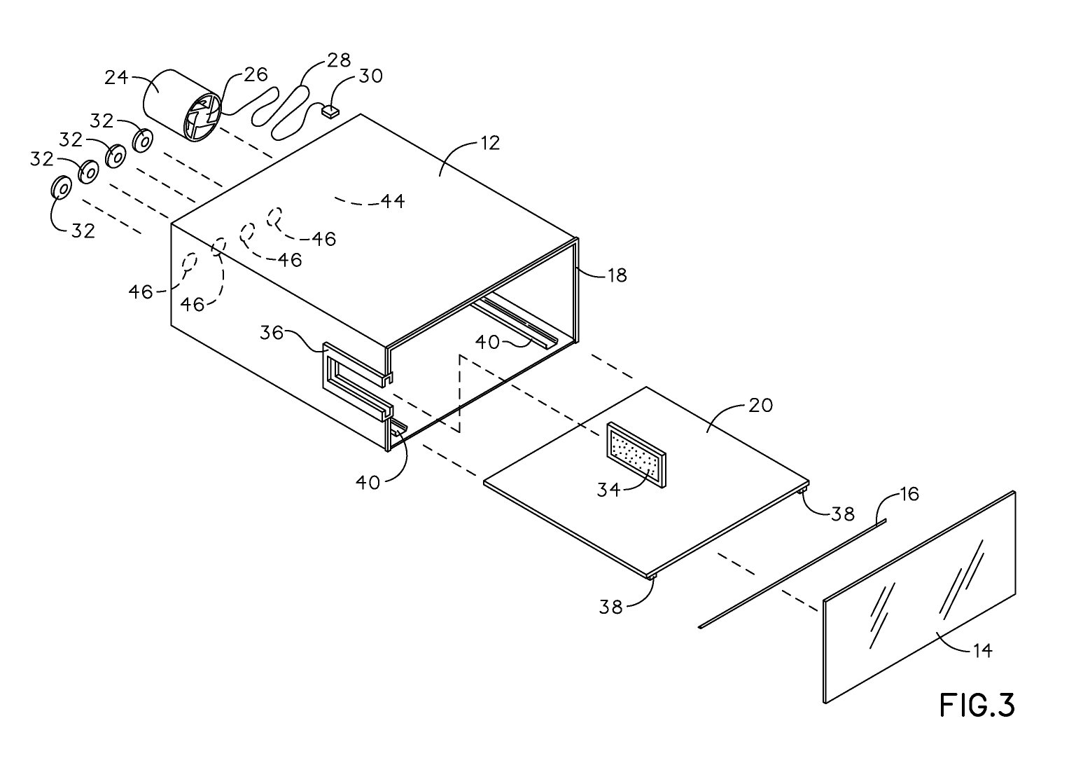

As depicted in FIGS. 1-3, storage apparatus 10 is configured to store any electronic device including, but not limited to, a video game console or other entertainment device (not shown). Storage apparatus 10 protects the electronic device from harmful particulates such as dirt and/or dust. Storage apparatus 10 comprises housing 12, door 14, rubber seal 18, shelf 20, fan 22, fan housing 24, fan motor 26, grommets 32, filter 34 and filter slot 36.

Housing 12 is made from plastic and has dimensions of approximately 12¾″×14¾″×6″. Housing 12 comprises an opening to allow a user to insert an electronic device (not shown) within housing 12 and onto shelf 20. Rubber seal 18 is disposed along the edges of the housing 12 opening. Door 14 is made from plastic or glass and is pivotably mounted to housing 12 by a self closing spring-loaded hinge 16, which is positioned along the width of the bottom wall of housing 12. This allows door 14 to be adjusted to an open position to allow the user to insert or remove an electronic device from housing 12 and to a closed position with door 14 positioned against rubber seal 18. In a preferred embodiment, door 14 is transparent to enable the user to visualize the interior of housing 12. It shall be appreciated that door 14 may be affixed to housing 12 by other means such as a sliding track.

Shelf 20 is slidably mounted to the bottom wall of housing 12. In particular, a pair of outer shelf slides 38 is affixed to the bottom of shelf 20. A pair of inner shelf slides 40 is affixed to the bottom wall of housing 12. This allows outer shelf slides 38 to engage with inner shelf slides 40, which enables the user to slide shelf 20 in and out of housing 12. Guide wheel brackets 42 may be used in combination with components such as wheels, rollers or ball bearings to enable inner shelf slides 40 and outer shelf slides 38 to slidably adjust with respect to one another. Inner shelf slides 40 and outer shelf slides 38 may also have a locking mechanism to prevent shelf 20 from detaching from housing 12.

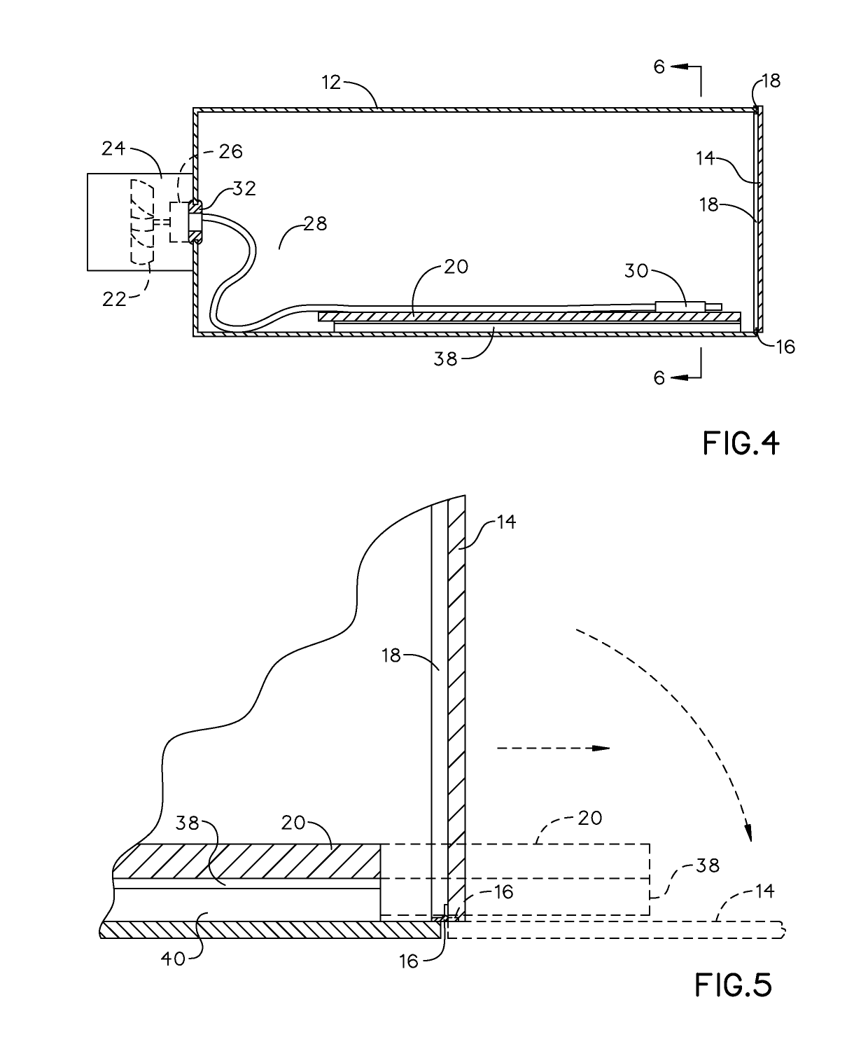

Fan housing 24 is mounted to fan opening 44 in housing 12. In a preferred embodiment, fan housing 24 is a cylindrical tubular member with an outer diameter of 3¼″ and an inner diameter of 2¾″. Fan 22 and fan motor 26 are secured within fan housing 24. The end of fan housing 24 configured to attach to fan opening 44 comprises a plurality of apertures. Any type of fan motor 26 known in the field may be used. In a preferred embodiment, fan motor 26 requires 10V to operate. As depicted in FIG. 4, power cord 28 is connected to fan motor 26 and extends through the apertures in fan housing 24 and into the interior of housing 12. Power cord 28 comprises power plug 30, which is a USB plug. Power plug 30 connects to the stored electronic device (not shown). As such, the electronic device supplies power to fan motor 26 via power cord 28.

Grommets 32 are disposed within grommet apertures 46 in housing 12. While the figures depict 4 grommets 32, it shall be appreciated that any alternative number of grommets 32 and corresponding grommet apertures 46 may exist. Grommet apertures 46 may be used to secure a plurality of cords or wires connected to the electronic device. For example, one grommet 32 can secure a power cord or wire to connect a video game console to an external power source such as a power outlet. Further, grommets 32 can secure audio and/or video cables to connect the video game console to a television. Unused grommets 32 can be plugged with a rubber component to prevent dust and/or dirt from entering housing 12 and onto the electronic device.

Filter 34 is an electrostatic and reusable filter that is slidably mounted to filter slot 36. Filter slot 36 comprises a metal track having approximate dimensions of 2″×4″. Filter 34 engages with the track of filter slot 36 to cover an aperture in a side wall of housing 12. A user can easily remove filter 34 from filter slot 36 to replace or clean the filter.

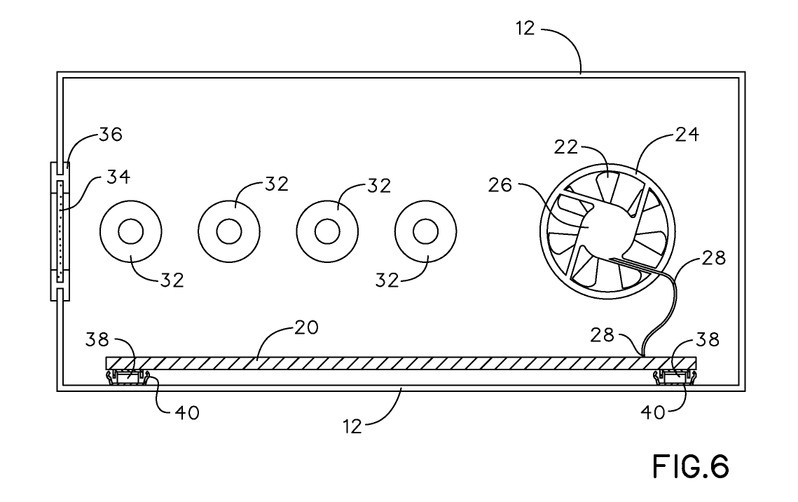

To operate storage apparatus 10, a user adjusts door 14 to an open position as depicted in FIG. 5. This allows shelf 20 to slide outside of housing 12 to enable a user to place an electronic device on shelf 20. Any necessary power cord, audio and video wires or cables are connected to the electronic device and placed through grommets 32 as shown in FIG. 6. The power cord is connected to an external power source such as a power outlet. The audio and video wires are connected to an appropriate device such as a television. Power plug 30 of fan 22 is connected to a receiving USB outlet on the electronic device. Shelf 20 is slidably adjusted such that the electronic device, cord and/or wires are stored within housing 12. Door 14 automatically closes via spring-loaded hinge 16 and creates a seal between door 14 and rubber seal 18.

The user turns on the electronic device and operates the device as normal. During this time, power from the electronic device is supplied to fan motor 26 via power cord 28. Fan motor 26 allows fan 22 to rotate rapidly, which pumps heat generated by the electronic device out of housing 12 and fan housing 24 and into the outside environment. This causes cooler ambient air to be forced through filter 34 and into housing 12. Filter 34 prevents dirt and/or dust from entering housing 12. This process helps to prevent the electronic device from overheating during its operation. Once the electronic device is turned off, fan motor 26 automatically shuts off. The electronic device can be stored within housing 12 when not in use. It shall be appreciated that the closed environment within housing 12 protects the electronic device from dirt and/or dust buildup both when the device is operating or being stored.

It shall be appreciated that the components of storage apparatus 10 described in several embodiments herein may comprise any alternative known materials in the field and be of any color, size and/or dimensions. This allows the apparatus to accommodate any variety and size of electronic devices. It shall be appreciated that the components of storage apparatus 10 described herein may be manufactured and assembled using any known techniques in the field.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. An electronic device storage apparatus for preventing harmful particulate exposure to the device while minimizing a likelihood the device will overheat when in use, the apparatus being configured to enhance the lifetime of the device, the apparatus comprising:
a housing member configured to store the device and comprising a door mounted to an opening of the housing member and at least one aperture on a back wall oriented parallel to the opening, wherein the at least one aperture is configured to secure a wire that connects the device to a power source external to the housing member;
a filter detachably coupled to an aperture in a side wall of the housing member; and
a fan system operably connected to the back wall of the housing member and configured to pump heat generated by the device out of the housing member and draw ambient air through the filter and into the housing member, thereby preventing the device from overheating.

2. The storage apparatus of claim 1, wherein the door is pivotably mounted to the housing member by a spring-loaded hinge.

3. The storage apparatus of claim 2, wherein the door is transparent.

4. The storage apparatus of claim 2, further comprising a rubber seal disposed along edges of the opening of the housing member.

5. The storage apparatus of claim 2, further comprising a grommet disposed within the at least one aperture on the back wall.

6. The storage apparatus of claim 2, further comprising a shelf slidably mounted to a bottom wall of the housing member, wherein the shelf is configured to support the device.

7. The storage apparatus of claim 6, further comprising a cylindrical tubular member affixed to an exterior portion of the housing member, wherein the cylindrical tubular member is configured to house the fan system.

8. The storage apparatus of claim 7, wherein the fan system comprises a set of blades and a motor.

9. The storage apparatus of claim 8, further comprising a USB plug affixed to the fan system and configured to connect with the device.
